(19) United States
(12) Patent Application Publication
(10) Pub. No.: US 2026/0247589 A1
(43) Pub. Date: Aug. 20, 2026

(54) TEMPERATURE REGULATION OF AN ELECTRICAL SYSTEM

(71) Applicant: KK Wind Solutions A/S, Ikast (DK)

(72) Inventors: Poul Thing, Ikast (DK); Jorgen Dahl Vestergaard, Kibaek (DK); Bjorn Rannestad, Aalborg (DK)

(21) Appl. No.: 19/469,292

(22) PCT Filed: Mar. 22, 2024
(86) PCT No.: PCT/DK2024/050065

§ 371 Date: Sep. 25, 2025

(30) Foreign Application Priority Data
Mar. 28, 2023 (DK) PA202370156
Apr. 27, 2023 (DK) PA202370206
May 26, 2023 (DK) PA202370259

(51) Int. Cl. H05K 7/20; H02B 1/56

(52) U.S. Cl. CPC H05K 7/20927; H02B 1/56

(57) ABSTRACT

A high-power electrical system includes a plurality of high-power electrical conductors configured to distribute power in the high-power electrical system in particular to an electrical component. At least one of the plurality of high-power electrical conductors includes a first end space apart from a second end by a middle segment. The middle segment includes at least one internal channel and one or both of the ends are monolithically formed with the middle segment. In addition, the high-power electrical system may include a temperature regulation system having a temperature regulation loop which includes the internal channel. The regulation system is configured for regulating the temperature of the high-power electrical system by controlling/guiding a fluid through the cooling loop, and thus, through the internal channel.

### FIELD OF THE INVENTION

The invention relates to high-power electrical system comprising an electrical conductor with an internal channel, a method of manufacturing such electrical conductor and use of such electrical conductor for temperature regulation of an electrical cabinet comprising the high-power electrical system.

### BACKGROUND OF THE INVENTION

In the art it is known e.g. from EP1057369 to have a hollow standard conductor like a tube. The interior hereof may be stabilized by a cross profile which forms ducts for carrying cooling water. Further form DE2402851 a water-cooled high voltage cable is known.

These two prior art documents represent the state of the art and thus a problem therewith in terms of connecting/separating the electrical conductor from the cooling fluid inside the electrical conductor at the end of the electrical conductor and the connection of the electrical conductor to an electrical component.

### SUMMARY OF THE INVENTION

The inventors have identified the above-mentioned problems and challenges related to temperature control and solved these problems by the present invention as described below.

In an aspect, the invention relates to a high-power electrical system comprising:
a plurality of high-power electrical conductors configured to distribute power in the high-power electrical system,
wherein at least one of the plurality of high-power electrical conductors is mechanically and electrically connected to a heat generating electrical component comprised by the high-power electrical system, and
a temperature regulation system comprising a temperature regulation loop,
wherein at least one of the plurality of high-power electrical conductors comprising a first end space apart from a second end by a middle segment,
wherein the middle segment comprises at least one internal channel which is included in the temperature regulation loop and configured to guide a temperature regulating fluid circulated in the temperature regulation loop, and
wherein at least one of the first end and the second end is monolithically formed with the middle segment.

A high-power electrical system should be understood as electrical systems of wind turbines, solar systems, utility grid, utility grid substations, at least part of the electric systems of an electrical vehicle, etc.

High-power should be understood as the power possible to draw by an electrical consumer at voltages at or above 110V such as up to 400 kV i.e. a high-power electrical conductor according to the present invention should be able to conduct at least 10 A such as up to 2000 A.

Monolithically uniting an end and the middle segment of an electrical conductor is advantageous in that it has the effect, that a manual process of assembling these parts is avoided. Thereby a possible source of error is eliminated.

Further, the footprint is reduced of an electrical conductor comprising an end which is monolithically formed with a middle segment. This is because no bushing or union nut is needed.

Further, a monolithically formed end and middle segment of an electrical conductor do not separate e.g., due to vibrations caused by the environment in which the electrical conductor is mounted.

The design of the conductor of the present invention may not have surplus material which is not used for conducting current when nominal current is supplied e.g. to a 1400 A power module. If extra material is used, this is preferably used for cooling/heating the conductor and/or its surroundings. The amount of such extra material can be determined relatively precise by the software which is used to design the conductor. As a rule of thumb, the larger surface for cooling, the higher amps is possible to conduct. The design software is able to put weight to amps, cooling/heating properties (cooling medium, surface, etc.) and frequency of the current when designing the geometry of the conductor/the individual conductor branches.

In an exemplary embodiment of the invention, the temperature regulation system is a cooling system configured for circulating a cooling fluid in the internal channel.

Such cooling system is circulating a cooling fluid, such as a liquid coolant. Such liquid coolant may e.g. be selected as a type of oil which may be non-electrical conductive and thereby work as both cooling fluid and isolator, water, deionized water, Glycol, liquid, metal such as Gallium, mercury, etc. The cooling system may circulate the cooling fluid in the temperature regulation loop, which in this case may be referred to as a cooling loop, with a flow speed in the range of 4 L/min to 10 L/min per power module. Therefore, the cooling system should be able to provide a flow of cooling fluid in the range of 48 L/min to 120 L/min in electrical systems having parallel power modules on each of three phases (12 power modules×4−10 L 7 min). The temperature of the cooling fluid is preferably below 55° C. in that it is often desired to maintain a temperature below 55° C. in the high-power electric system.

In this embodiment, the internal channel may be referred to as an internal cooling channel defined by/inside the conductor. The internal cooling channel is as mentioned configured to guide a cooling fluid through at least the middle segment of the high-power electrical conductor (sometimes referred to simply as conductor). In this way, the temperature of the high-power electrical conductor, especially around the internal cooling channel, can be reduced.

Thus, sufficient cooling via the internal cooling channel may lead to an increase in current possible to conductor to e.g. a power module and/or handled by a the power module in that temperature is then no longer as limiting a factor compered to power modules of known electric system only cooled by an air flow on the outside of the electrical conductor.

The cooling system of the temperature regulation system may include a heat pump, heat exchanger or similar for facilitating a temperature decrease of the cooling fluid circulated in the internal channel.

An internal cooling channel is advantageous in that it has the effect, that an efficient downward temperature regulation of the electrical conductor is possible.

In an exemplary embodiment of the invention, the temperature regulation system is a heating system configured for circulating a heating fluid in the internal channel.

Circulating a heating fluid is advantageous e.g. as part of a method of starting up an electrical system after standstill of the electrical system. It may be critical e.g. both to safety and functionality that the conductors e.g. are dry prior to power up of the system and this may be ensured by heating up the conductor.

In an exemplary embodiment of the invention, the temperature regulation system is a combined heating system and cooling system for circulating a temperature regulating fluid in the internal channel so at so regulate a temperature of the at least one of the plurality of high-power electrical conductors.

The same fluid circulated in the internal channel may be used for heating or cooling depending on the temperature of this fluid and the ambient temperature such as the temperature of the conductor. Hence, prior to start-up, the conductor may have a temperature that is below the temperature of the fluid and thus the fluid may act as a heater for the conductor. During operation, the temperature of the fluid may be lower than the temperature of the conductor and thus act as a cooler for the conductor.

Thus, even though the channel may be referred to as a cooling channel it may in fact be used to heat up the conductor before stat of operation of the electric system. In such situation e.g., where a cooling fluid is warmer than the ambient temperature of the conductor, it may be more appropriate to refer to the internal cooling channel as simply an internal channel. Such internal channel may be used to circulate a fluid with which it is possible to regulate temperature of the busbar comprising the internal channel. In this way it is possible to either increase or decrease the temperature of the busbar and thereby of the cabinet in which the busbar is enclosed. This is advantageous in that it has the effect, that drips of water e.g. condensation on the busbar can be vaporized prior to conducting current through the busbar. In this way the risk of arc flash occurring is reduced.

In an exemplary embodiment of the invention, the at least one internal channel extends in a longitudinal direction of the middle segment.

Thus, even though not included in the first or second ends, the internal channel extends between the first and second end. Thereby if extending throughout the entire middle segment, the entire middle segment is able to be temperature regulated by a fluid flowing in the internal channel.

It should be mentioned that an internal channel having an S-like form from side to side in the transversal direction of the electrical conductor is also considered as extending in the longitudinal direction of the electrical conductor. And that the ends may also comprise internal channel i.e., the internal channel may extend from one end to the other of the conductor.

In an exemplary embodiment of the invention, the at least one internal channel extends in the same plane through the middle segment of the middle segment.

This is advantageous in that it has the effect, that a current path through the middle segment is only “blocked once” by the internal channel contrary to an embodiment where the internal channel extends e.g. diagonal inside the middle segment in the longitudinal direction of the middle segment.

It should be mentioned that this same plane may be a plane in the X direction or in the Y direction of the middle segment.

In an exemplary embodiment of the invention, the at least one internal channel extend at least one quarter, preferably at least half, most preferably at least three quarters of the longitudinal length of the middle segment.

An internal channel extending in the longitudinal direction of the middle segment is advantageous in that it has the effect that a large part of the electrical conductor is able to exchange heat with the flow of temperature regulating fluid such as a cooling fluid in the internal channel.

Note that the internal channel extends, by its cross-sectional area, also in the transversal direction of the middle segment.

In an exemplary embodiment of the invention, the at least one internal channel is longer than the shortest distance between the two ends of the middle segment.

The end of the middle segment is defined as the transition between the middle segment and the first and second ends respectively of the electrical conductor. I.e. as the distance between a terminal or end, connected to the middle segment, whether this connection is monolithically or not.

In an exemplary embodiment of the invention, the at least one internal channel extends in the longitudinal direction of the middle segment following a zigzag path in the same plane of the middle segment from one side of the middle segment to a second side of the middle segment.

This is advantageous in that it has the effect that a large area of the middle segment and thereby of the electrical conductor may be cooled/temperature regulated by a flow of fluid in the channel. Such design is a trade-off between the desired cooling of the entire conductor, flow of fluid and conductance of current through the conductor.

The same plane should be understood as the same layer of a middle segment manufactured by additive manufacturing. Here one layer should be understood as a plurality of layers i.e. the number of layers which needed to define the internal cooling channel.

In an exemplary embodiment of the invention, the plurality of high-power electrical conductors comprises at least two, preferably at least three, most preferably at least four internal channels.

Having more than one internal channel such as more than one internal cooling channel is advantageous in that it has the effect, that the conductor then has more surface when high frequency current is conducted due to the skin effect. Further, this is advantageous in that it has the effect, that a larger part of the cross-sectional area of the electrical conductor is possible to temperature regulate. Further, this is advantageous in that it has the effect, that heating/cooling fluid having different temperatures can flow through different parts of the electrical conductor. A plurality of channels also allows to circulate the same cooling forth and back between the ends of the middle segment/first and second ends. Alternative, it allows to have several separate flows.

A plurality of internal channels may be provided in different layers of the cross-sectional area of the conductor, aligned, etc. to reduce impact om the current path through the conductor as little as possible.

In an exemplary embodiment of the invention, the at least one internal channel branches off in at least two internal channel branches.

This is advantageous in that it has the effect, that if the electrical conductor branches off in two or more conductor branches, each these conductor branches may comprise an internal channel branch and thereby each be cooled/temperature regulated.

In an exemplary embodiment of the invention, at least two of the internal channel is configured for conducting a flow of temperature regulating fluid of different temperature.

This is advantageous in that different parts of the conductor can be cooled different. As an example, where the conductor has the highest temperature (and an internal channel), the fluid with the lowest temperature is conductor. Hence, e.g. a return path may be through a part of the conductor where which is colder than where a forward path is running.

In an exemplary embodiment of the invention, the at least one internal channel has a geometry selected from the list comprising: gyroid-like, web-like, circular, oval, triangular, rectangular, square, pentagon and multi sided.

The design of the geometry of the internal channel should preferably provide as little flow resistance as possible. With this the it may be appreciated to establish some swirling effects in the flow through the internal channel to increase e.g. a cooling effect thereof. This may be achieved by providing the walls of the internal channel with recesses in a predetermined pattern such as known from a rifle barrel. In addition, as mentioned it is desired to have a surface of the channel that is as large as possible to increase e.g. the cooling capacity.

The combination of these demands may by the software designing the conductor result in what is referred to as a bionic design i.e. a logic design in which current paths are not predictable in size or direction.

In an exemplary embodiment of the invention, the at least one internal channel is configured to comprise a pipe.

A pipe/polymer tube e.g. in the form of an insulated hose may be inserted into the internal channel e.g. when the electrical conductor with internal channel is manufactured/prior to or after the conductor is mounted in the system. This is advantageous in that it has the effect, that no connection of an external channel to the internal cooling channel is needed. The pipe may simple be circulating the cooling fluid from a heat exchanger through the electrical conductor via the internal channel and back to the heat exchanger. And vice versa with heating fluid.

In an exemplary embodiment of the invention, the at least one internal channel comprises a plurality of flow guides.

Flow guides are advantageous in that they have the effect that they may be designed to establish a particular flow of cooling fluid inside the internal channel. Such particular flow may include establishing a swirling effect in the flow of e.g. a cooling fluid inside the internal channel and thereby increase cooling effect of the cooling fluid.

In an exemplary embodiment of the invention, individual flow guides of the plurality of flow guides have a non-uniform geometry.

A non-uniform geometry should be understood as one flow guide may be cylindrical, one may be oval, one may be triangular, etc.

Having flow guides with a non-uniform geometry is advantageous in that it has the effect that a non-uniform flow of cooling fluid through the internal cooling channel is obtained. A non-uniform flow of cooling fluid may lead to an increased cooling effect of the cooling fluid.

In an exemplary embodiment of the invention, individual flow guides of the plurality of flow guides is outgrowing from an inner wall of the at least one internal channel in different directions.

Hence in an embodiment, one flow guide may outgrow from one side of a rectangular internal channel towards an opposite second side. Another flow guide may outgrow from the second side towards the one side. Another flow guide may outgrow from one of the third and fourth sides, etc.

Such varying outgrowing flow guides may lead to a desired or controlled flow of cooling fluid which may increase or decrease flow speed, create a swirling effect, etc.

In an exemplary embodiment of the invention, individual flow guides of the plurality of flow guides is outgrowing.

In an exemplary embodiment of the invention, the at least one internal channel is monolithically formed with a channel extension.

A channel extension facilitates easy connection to e.g. a cooling loop of an external cooling channel. Monolithically uniting the internal channel and the channel extension and thereby part of an external (to the high-power electrical conductors or middle segment hereof) channel is advantage in that mounting of the internal channel to e.g. a cooling system is easy. An external channel/cooling loop such as a plastic pipe may be connected to the channel extension and thereby with the inner channel with a hose clamp. Thus, easy mounting of cooling loop is possible.

It should be mentioned that the channel extension may be of a different type of material than the conductor. In such case it may be more correct to refer to a polylithic formed internal channel and channel extension.

In an exemplary embodiment of the invention, the part of the channel extension ends in a threaded part.

This is advantageous in that it has the effect that an external channel may be connected easy with a union nut or bushing to the channel extension and thus to the inner channel.

In an exemplary embodiment of the invention, the part of the channel extension is manufactured in the same electrically conductive material as the middle segment or one of the end segments of the electrical conductor.

This is advantageous in that it has the effect, that the channel extension may be manufactured in the same process as the electrical conductor such as with an additive manufacturing process.

In an exemplary embodiment of the invention, the at least one internal channel is an internal cooling channel connectable to an external cooling loop via a cooling channel inlet and a cooling channel outlet.

This is advantageous in that it has the effect, that the internal cooling channel may be connected to an external cooling channel.

In an exemplary embodiment of the invention, the channel inlet and/or the channel outlet is implemented as a threated part into or out from the electrical conductor.

This is advantageous in that it has the effect, that an external channel may easily be connected by screwing it to the electrical conductor and/or e.g. clamping it to the electrical conductor e.g. by a union nut.

In an exemplary embodiment of the invention, the channel inlet and/or the cooling channel outlet is provided in the first end, in the second end and/or in the middle segment.

In an exemplary embodiment of the invention, the high-power electrical conductor is selected from the list comprising: main busbar, transition busbar and current balancing busbar.

A main busbar should be understood as an electrical conductor distributing current in an electrical cabinet, a switchgear, panel board or busway enclosure, typically, from one or more cables entering the electrical cabinet to electrical components located inside the electrical cabinet. Typically, the main busbar extends in the width (X direction) or in the height (Y direction) of the electrical cabinet. The main busbar may be fastened to the back plate of the electrical cabinet.

A transition busbar should be understood as a busbar connecting a main busbar or cable with another main busbar, another transition busbar, with an electrical component, or the like. A transition busbar may also be referred to as a connection or transition piece for connecting two or more electrical components. Typically, a transition busbar extends in two or more directions, where one of these directions is towards the opening of the electrical cabinet (Z direction). Another of these directions is typically perpendicular or parallel to e.g. the main busbar to which transition busbar is connected. The transition busbar may comprise two legs at one end for connecting e.g. two paralleled power modules to one main busbar or to another transition busbar.

A current balancing busbar should be understood as a variant of a transition busbar. A current balancing busbar may e.g. be a transition busbar where the two legs connecting the paralleled power modules are connected/shut circuited. This is advantageous in that it has the effect, that if the current balancing busbar is connected to two parallel connected power modules, and the current into or out of these two power modules are not the same, due to the connected legs heat and current is conducted in one larger leg. In this way the current and heat is balanced in the current balancing busbar.

In an exemplary embodiment of the invention, the high-power electrical system further comprises an electric cabinet comprising the plurality of high-power electrical conductors, wherein the plurality of high-power electrical conductors are connected to a high-power load or a high-power power supply.

A high-power load or grid to which the high-power electric system of the present invention is connected may e.g. be a utility grid, an energy storage, a power-to-x system such as an electrolyser, etc.

In an exemplary embodiment of the invention, the high-power electrical system is comprised by one from the list comprising: a renewable energy generation plant, a land vehicle and a floating vessel.

A renewable energy generation plant includes a wind turbine, solar system, etc. A land vehicle includes a light-duty vehicle, a heavy-duty vehicle, etc. A floating vessel includes a ship.

In an exemplary embodiment of the invention, the at least one heat generating electrical component comprise a semiconductor switch.

A semiconductor switch may be an IGBT, MOSFET or the like implemented in a heat generating electrical component such as a rectifier, inverter, converter or the like. The semiconductor switches may be embedded in one unit referred to as a power module. A power module may thus comprise semiconductor switches in a particular configuration.

In an exemplary embodiment of the invention, the middle segment is monolithically formed in an electrically conductive material.

Thus, independent of geometry, the middle segment is one piece which is advantageous in that it has the effect, that no need to manually connect middle segment parts. Thereby is mounting speed of the electrical system in which the electric conductor is mounted increased and at the same time risk of human errors are reduced if not eliminated with respect to assembling of the electrical conductor.

A one-piece middle segment may be manufactured by an additive manufacturing process, a moulding process, extrusion process or similar.

In an exemplary embodiment of the invention, the middle segment is monolithically formed in a first end with the first end of the electrical conductor and monolithically formed in a second end with the second end of the electrical conductor.

In an exemplary embodiment of the invention, the high-power electrical conductors is at least partly manufactured by an additive manufacturing process.

Manufacturing an electrical conductor according to the present invention by an additive manufacturing process is advantageous in that not only the ends and middle segment including internal cooling channel may be monolithically formed. But also cooling channel inlets and outlets may be manufactured monolithically formed to electrical conductor ends and/or middle segment.

This is advantageous in that it has the effect, the internal cooling channel that no fittings or union nots are needed to connect the internal cooling channel to an external cooling channel.

In an exemplary embodiment of the invention, the middle segment comprising a plurality of conductor branches.

One conductor branch may be designed and subsequently produced in a harmonica-like shape, spiral-like shape, etc. leading to a plurality of airgaps between parts of the same or neighbouring conductor branch.

It should be mentioned that a high-power electrical conductor may be built from a mix of conductor branches of different geometries.

In an exemplary embodiment of the invention, the one or more conductor branches are identical.

Identical may be understood as the same cross-sectional area i.e. a cross-section area of 2.g. 0.5 mm², 1 mm², 1.5 mm² etc. up to e.g. 6 mm² or even higher.

In an exemplary embodiment of the invention, a cross-sectional area of the one or more conductor branches are equal to or below 200 mm², preferably below 150 mm², preferably below 100 mm², preferably below 50 mm², preferably below 10 mm², most preferably between 0.5 mm² and 5 mm².

The high-power electrical conductor is advantageous in that even though each of the conductor branches is having a cross-sectional area of 10 mm² or 20 mm², the high-power electrical conductor may still be flexible. It is however evident that the thinner conductor branches the less a force is needed to deform the high-power electrical conductor. In case an additive manufacturing machine is able to build conductor up to e.g. 5000 mm², this may needed to some applications

In an exemplary embodiment of the invention, said high-power electrical conductor (1) has a resonance vibration frequency of at least 5 Hz, for example at least 20 Hz, for example at least 30 Hz, for example at least 70 Hz, for example at least 150 Hz for example at least 300 Hz, for example at least 500 Hz.

The electrical conductor is advantageously designed and subsequent manufactured so that it has a resonance vibration frequency associated with relative motion between the first end segment and the second end segment that is does not coincide with a natural frequency of the system in which it is included. This is to avoid vibrations initiated by natural frequencies from such electric system or mechanical system. An example of a mechanical system is a wind turbine which may have a natural frequency of 5 Hz. The resonant frequency of the conductor may be changed by applying a structure e.g. along the length or width of the conductor with the only purpose of avoiding a particular resonant frequence. The structure may include a protrusion, wedge, etc.

In an exemplary embodiment of the invention, a channel inlet or a channel outlet of said internal channel is provide in said first or second end segments.

In an exemplary embodiment of the invention, said first or second end segment is a U-shaped end segment.

Having the channel inlet or outlet in the end segments especially in a U-or E-shaped end segment is advantageous in that when connecting to anther busbar via the end segment, the internal channel of one conductor can be continue in another conductor.

In an exemplary embodiment of the invention, the high-power electrical conductor according to any of the above is manufactured according to the described method below.

In an aspect, the invention relates to a use of a high-power electrical conductor comprising an internal channel for temperature regulation of an electrical cabinet enclosing a high-power electrical system according to any of the preceding claims.

In an aspect, the invention relates to a method of manufacturing a high-power electrical conductor comprising an internal channel, the method comprises the step of by an additive manufacturing process:
provide a first layer of electrically conductive material,
provide a plurality of subsequent layers of the electrically conductive material thereby forming a first end, a middle segment and a second end of the high-power electrical conductor,
wherein the method is characterized in that a layer of the high-power electrical conductor added to a previous layer of the high-power electrical conductor is only partly covering the cross-sectional area the previous layer.

This is advantageous in that the non-covered part of the cross-sectional area of the middle segment is thus layer by layer forming the geometry of an internal channel.

In this way an internal cooling channel with almost any “printable” geometry may be possible to manufacture. This include flow guides inside the internal cooling channel which may also be manufacture in the same way i.e. formed layer by layer and thus also having any “printable” geometry.

In an exemplary embodiment of the invention, part of the previous layer not covered by a subsequent layer is a middle part of the cross-sectional area of the high-power electrical conductor.

In an exemplary embodiment of the invention the part of the previous layer not covered by a subsequent layer is within the middle 95% of the previous layer, preferably within the middle 80% of the previous layer, most preferably within the middle 50% of the previous layer.

It should be noted, that if several individual cooling channels are provided in the conductor, these may be distributed equally across the cross-section of the conductor.

### THE DRAWINGS

For a more complete understanding of this disclosure, reference is now made to the following brief description, taken in connection with the accompanying drawings and detailed description, wherein like reference numerals represent like parts. The drawings illustrate embodiment of the invention and elements of different drawings can be combined within the scope of the invention:

FIG. 1a illustrates a first electrical local connecting busbar with a twisted geometry,

FIG. 1b illustrates a second electrical local connecting busbar with a weblike geometry,

FIG. 1c illustrates a third electrical local connecting busbar with a bionic design,

FIG. 2 illustrates a flow chart for manufacturing an electrical local connecting busbar,

FIG. 3 illustrates a conductor with an internal channel,

FIG. 4 illustrates a middle segment in a cross-sectional view,

FIG. 5 illustrates a conductor with an internal channel branching off,

FIG. 6 illustrates an internal channel with channel extensions,

FIG. 7 illustrates an internal channel with flow guides, and

FIGS. 8-11 illustrates different variants of conductors with different variants of internal channels.

### DETAILED DESCRIPTION

The present invention is described in view of exemplary embodiments only intended to illustrate the principles and implementation of the present invention. The skilled person will be able to provide several embodiments within the scope of the claims.

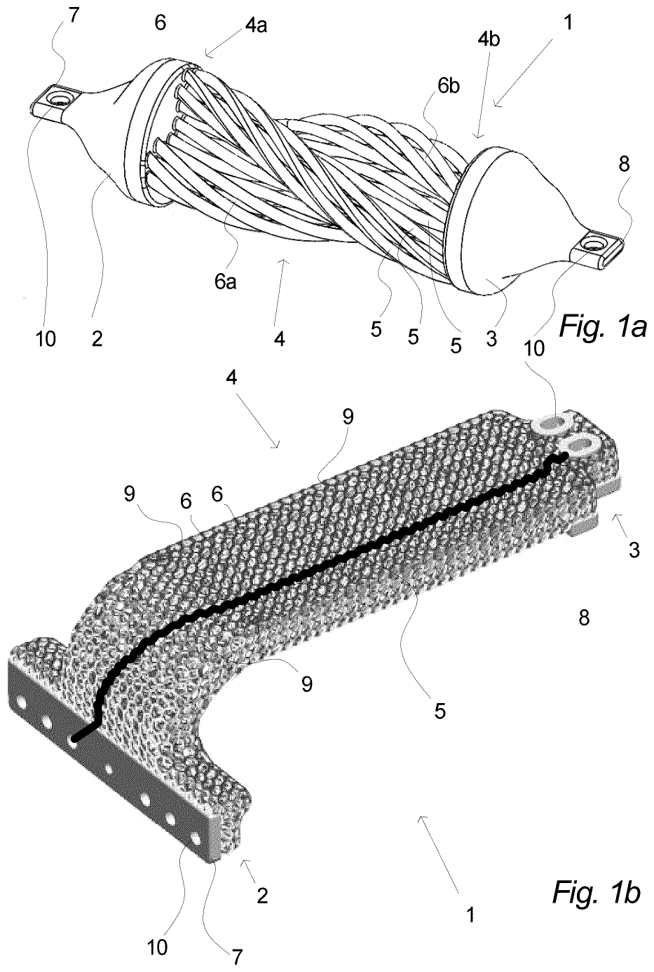

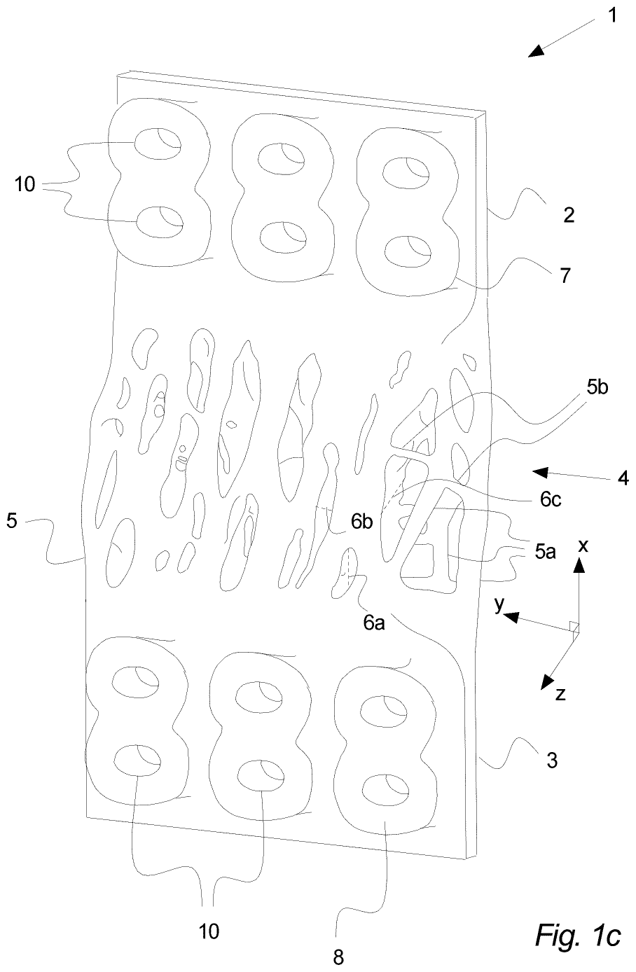

FIG. 1a-1c illustrates various embodiments of an electrical conductor 1 according to the present invention. FIG. 1a illustrates an electrical conductor 1 having a twisted geometry/design. The electrical conductor 1 comprises a first end 2 and a second end 3, where the second end 3 being distal to the first end 2 and spaced apart from each other by a middle segment 4.

The middle section 4 in this particular embodiment comprises a plurality of conductor branches 5. In this particular embodiment the individual conductor branches are spaced apart by air gaps 6 both in the longitudinal and 6a transversal direction 6b of the electrical conductor 1. This twisted design of the conductor branches adds flexibility to the conductor 1 and thus the ability to absorb vibrations. Further, the design is lightweight and easy to mount.

In this particular embodiment, the first end 2 comprises a first terminal 7 and the second end 3 comprises a second terminal 8. The first and second terminals 7, 8 may comprise one or more terminal holes 10 for connecting the electrical conductor 1 to other electrical components. The electrical conductor 1 is configured to support conductance of an electric current between the first and second terminals 7, 8.

Each of these two terminals 7, 8 may, via terminal holes 10, clamps, plugs or other electrical connection means, for example be galvanically coupled to terminals, busbars, components (such as breakers, contactors, power modules, reactors, etc.) and other electrical conductors according to the present invention, etc. of an electrical installation. Typically, the electrical conductor 1 and thus the terminals, busbars, components, etc. to which it may be connected would be comprised by an electric box i.e. located inside an enclosure such as a panel, cabinet, etc.

In various embodiments, the electrical conductor 1 may have several first ends 2, several second ends 3, several first terminals 7, and/or several second terminals 8.

FIG. 1b illustrates an electrical conductor 1 having a web-like or lattice-like geometry/design. As the electrical conductor 1 illustrated in FIG. 1a, the electrical conductor illustrated in FIG. 1b comprises a first end 2 and a second end 3 separated by a middle section 4. The first end 2 may comprise a first terminal 7 and the second end 3 may comprise a second terminal 8. The first and second terminals 7, 8 may comprise one or more terminal holes 10 for connecting the electrical conductor 1 to other electrical components.

Between the two terminals 7, 8 conductor branches 5 in a web-like structure extend (only one is highlighted). These conductor branches meet and branch off in a plurality of intersection points 9. Note that the first and second ends 2, 3 are also partly manufactured as a web-like design as the middle segment 4. Also note, that the first and second terminals 7, 8 comprise more than one terminal hole 10. The terminal holes 10 of the terminals 7, 8 is made in a part of the ends 2, 3 which has non-perforated surface i.e. a surface different from the web-like surface of e.g. the middle segment 4 of the electrical conductor in this particular embodiment. The planar contact surface of the terminals 7, 8 around the terminal holes 10 is preferred to provide a connection surface to another flat surface with as little resistance as possible and sufficiently strong contact surface between bolt/nut and electrical conductor 1.

FIG. 1c illustrate an electrical conductor having a bionic geometry/design. As the electrical conductor 1 illustrated in FIG. 1a and 1b, the electrical conductor illustrated in FIG. 1c comprises a first end 2 and a second end 3 separated by a middle section 4. The first end 2 may comprise a first terminal 7 and the second end 3 may comprise a second terminal 8. The first and second terminals 7, 8 may comprise one or more terminal holes 10 for connecting the electrical conductor 1 to other electrical components.

The middle segment 4 in this embodiment is of a so-called bionic design, preferably achieved as a computer generated design. Such computer-generated design is provided based on input to a computer program controlling an additive manufacturing machine/process or able to export data to a controller of an additive manufacturing machine/process such as from a user or another computer. Input may include dimension, maximum current to be conducted, required strength, maximum deflection (elastic or plastic), etc. As the electrical conductor illustrated in FIG. 1b, the electrical conductor of this particular embodiment comprises both longitudinal conductor branches 5a and transversal conductor branches 5b. It is noted, that together the conductor branches 5a, 5b forms a transversal conductor branch outgrowth i.e. if seen in a side view, the electrical conductor 1 of FIG. 1c would be thicker at the middle section 4 than at the ends 2, 3. The conductor branches 5 are spaced apart in space by air gaps 6 in both X (6a), Y (6b) and Z (6c) directions. Further note, that the terminals 7, 8 are designed with a planar surface to obtain best possible contact with a component having a planar surface, to which the electrical conductor 1 is to be connected to, such as clamped against, via for example bolt and nuts. Also note, that independent from the geometry of the ends 2,3, the terminals 7,8 are aligned/raised so that the contact surface for, e.g., all three terminals 7 are in the same plane.

The above embodiments of an electrical conductor 1 all feature airy geometries having air gaps 5 between conductor branches 6. The electrical conductor 1 of the present invention may in other embodiments feature other airy geometries such as web-like, gyroid-like, lattice-like, etc., as described in more detail herein, which in various embodiments may provide improved cooling, reduced material consumption, improved flexibility, and/or other advantages described in more detail herein. The term ‘-like’ is used in connection with gyroid-like, lattice-like, etc., to emphasize that it is an airy geometry resembling the named structure, rather than a specific systematic structure, that is relevant in preferred embodiments of the invention.

It should be noted that the three different designs of electrical conductors of the present invention illustrated in FIG. 1a-1c is not limiting for the designs or geometries or structures that is possible to manufacture according to the present invention. Other designs that are possible to represent digitally and transfer to an additive manufacturing device and thus manufacture by additive manufacturing is considered to fall with the scope of the present invention. This includes designs having plane surfaces with internal ducts, manufactured by different materials, manufactures with protrusions or recesses, manufactured to have auxiliary functions beside conducting current, etc. Particularly, high-power conductors are advantageous to manufacture according to the present invention.

Note that embodiment of the invention, such as the above-described electrical conductors, may comprise further terminals 7, 8 between the ends 2, 3, which are not illustrated. Also note, that a plurality of the illustrated electrical conductors 1 may be connected to form a complete electrical conductor. In this case the first and second end 2, 3, is referred to as the ends of the complete electrical conductor which may comprise terminals 7,8 and e.g. terminal holes 10 for connecting the complete electrical conductor to other components. Between these first and second ends 2, 3 of the complete electrical conductor, terminals 7, 8 of a plurality of electrical conductors as illustrated may be connected.

The cross-sectional area of the conductor/conductor branches can be exploited to its full potential in an electrical conductor of the present invention. The conductor is designed and manufacture to have a cross-sectional area that is able to comply with requirements to current to be conducted without have excess of material used. The design of the present conductor may not have surplus material which is not used for conducting current when nominal current is supplied e.g. to a 1400 A power module. If extra material is used, this is used for cooling the conductor or a safety margin. The amount of such extra material can be determined relatively precise by the software which is used to design the conductor. As a rule of thumb, the larger surface for cooling, the higher amps is possible to conduct. The design software may be able to put weight on amps, cooling properties (cooling medium, surface, etc.), frequency of the current when designing the geometry of the conductor, etc. when designing the conductor. Accordingly, a conducting cross-sectional area of a conductor as illustrate in FIG. 1b may be 80 mm² may in certain embodiments be sufficient to conduct a current of 1300 A due to the airy design allowing a very advantageous cooling. In fact, tests have shown that the temperature of a conventional massive busbar with a conducting cross-sectional area of 516 mm² conducting 1300 A increases to a temperature where neighboring components of plastic is in risk of melting.

Hence, it should be noted that the conductor may be designed and subsequently manufactured so that a percentage of the cross-sectional area of the electrical conductor e.g., above 80% such as between 90% and 100% is used to conduct current during normal operation. This is in contrary to known massive busbars that does not exploit the material in its center to conductor current. This is at least true for most frequencies of currents conducted in high-power systems including renewable systems, vehicles and the like.

The high percentage of utilization of cross-sectional area for conducting current compared to known massive conductors is possible to obtain in that the conductor of the present invention and thus the individual conductor branches because they are designed with a cross-sectional area that sums up to be able to conduct a current of a given frequency. Further, the material reduction is also made possible because of the possibility of cooling also inside the conductor. In fact, a conductor branch may along most of its length, in some embodiments along all of its length, be cooled from all angles i.e. a 360° cooling of the conductor branches is possible.

As mentioned, a conductor of the present invention may form an airy geometry which depending on the kind of airiness may not facilitate a secure or robust platform or structure for fastening the conductor e.g. to the electric cabinet. Accordingly, in proximity of through-holes for fastening the conductor or through-holes, e.g. terminal holes, for connecting the conductor to components or other conductors, the geometry of the conductor may not be airy. Preferably, around a through-hole the density of the conductor is higher or more concentrated to form an, e.g., planar surface and thereby provide the best possible preconditions for conducting current between two parts of a joint and to distribute the force required to fastening a conductor in the joint or to a support structure. Hence, a through-hole may be designed as a cylinder through which a bolt may pass through and with planar upper and lower parts extending from the periphery of the cylinder to facilitate the force and/or current distribution in the joint. Other mounting and/or terminal points may be preferred in some embodiments, such as flanges, protrusions, plugs or sockets, etc., with or without through-holes, but with the same consideration of ensuring sufficient robustness and stability of the electrical conductor for the intended mounting or connection method. The through-holes could be 6 mm, 8 mm, 10 mm or 12 mm in diameter.

It should be mentioned that terminals for electrical connection may be positioned at or between the ends of an electrical conductor. Thus, in principle, a conductor may be manufactured by an additive manufacturing process and when the first end and first part of the middle segment is manufactured these may be rolled onto a conductor holder as the middle segment is continued to be manufactured. Alternative, the conductor is guided out of the printing areas e.g. by a conveyer belt as the conductor is manufactured. This may result in a long conductor with two ends. Either during manufacturing or after, terminals may be made in the conductor and also after manufacturing, the conductor may be cut into desired lengths. In this way, terminals may be manufactured or provided either at the ends or between the ends of the conductor.

The term monolithic is in this description used to describe the geometry or structure of an electrical conductor according to the present invention. Such conductor is preferably manufactured by an additive manufacturing process and thereby, it is manufactured as a single piece, unit or block from one end to the other or at least one end and a middle segment is manufacture as a single piece. Such conductor may thus be formed from a single material as a single piece, unit or block where its one or more ends are monolithically formed with a middle segment connecting the one or more ends i.e. monolithically formed or formed should be understood as made in one continuous process with no need for additionally adding one part to another I.e. one or more ends are manufactured together with the middle segment as one unit with no connections such as welding, soldering, or by any clamping or fastening means, except for the type of micro binding intrinsic to the particular additive manufacturing technology utilized, such as, e.g., layer-by-layer melting, sintering, liquid binding, spraying, etc. With this said, it should be mentioned, that it is possible to add additional elements such as terminals, cooling fins, etc in a post manufacturing process e.g., by a cold spray process.

Put in another way a conductor of the present invention is the result of a process forming the conductor in one structure, a conductor composed of an electrically conductive material without joints or seams and thus constituting a conductor as a rigid whole exhibiting a rigidly fixed uniformity. To such conductor it is possible to connect additional conductors via terminals and thereby branch off one current path to two or more current paths or vice versa.

It should be mentioned that the conductor may be manufactured from more than one type of material. In this situation, the conductor could be said to be polylithic. The term polylithic should in this context be understood as a geometry or structure of an electrical conductor that is manufactured in one piece as a monolithic structure, as described above, where the conductor is manufactured from two or more materials. Hence, a polylithic conductor of the present invention is a conductor resulting from a process forming the conductor in one structure where the process is using two or more different materials. Such two or more materials may be a combination of electrical conductive or non-conductive materials.

In most embodiments, the electrical conductor 1 is designed to comply with high voltages i.e. voltages above 24V such as 110V, 230V, 400V, 690V, 1000V, 1500V and up to kV systems. just to mention a few voltage levels of an electrical installation in which the electrical conductor 1 of the present invention would be suitable. In terms of current, an electrical conductor 1 according to the present invention may be designed to conduct several hundreds of amps (16, 32, 64, and so on up to 100, 200 and so on up to e.g. 900 A) up to a couple of thousand amps (1000 A-3000 A). Electrical conductors may be designed to conduct higher currents than 3000 A e.g. by improving cooling of the conductor in combination with an increased cross-sectional area of the conducting part of the conductor.

Mentioning these voltages, it should be noted, that in principle there are no lower limits as to the voltage and current. I.e., versions of the electrical conductor may be designed to be used in, e.g., 3.3V, 5V, 9V, 12V, 15V, 20V, 24V or 48V systems, such as USB power delivery PD systems, conducting currents below, e.g., 10 A, such as 5 A, 3 A, 2.4 A, or 2 A just to mention a few examples.

Thus, the electrical conductor 1 of the present invention is suitable for use in almost any type of electrical installation. This includes everything from low voltage to high voltage AC and or DC systems where transfer/conducting of current or communication signals is needed.

The present invention is particularly advantageous for electrical busbars designed for high-power electrical systems, e.g. from 10 kW and up, such as 22 kW, 50 kW, 110 kW, 150 kW, 225 kW, 300 kW, 350 kW, 500 kW, 800 kW, 1 MW, 2 MW, 3 MW, or even higher, such as e.g. 5 MW or 10 MW systems, with voltages of e.g. 110V, 230V, 400V, 690V, 800V, 1000V, 1500V, 6 kV or e.g. 10 kV, and currents from e.g. 16 A, 32 A or 64 A, to several hundreds, e.g. 100 A, 200 A or 500 A, or even thousands, e.g. 1000 A to 4000 A. By local connecting busbar is referred to busbars for local connections inside such a high-power electrical system, e.g. contained inside an electrical cabinet housing a power converter, inverter, transformer, generator, electric motor, breaker, high-power battery system, battery charger, or similar power systems, possibly including capacitors, reactors or inductors, power resistors, dump loads, etc. A system, component or conductor may be categorized as a high-power system, component or conductor if it is operating at currents in the range of 800-1000 A or higher.

Non-limiting examples of such electrical installations/systems include energy facilities such as grid components such as substations with grid support, voltage regulation, power to x plants, etc., energy generating systems such as wind turbines, wind farms, solar plants, etc., electric installations in a private homes and industry, industrial machines, household appliances, etc. and means for transportation such as airplanes, heavy duty vehicles, light duty vehicles such as automobiles, trains, ships, etc.

Accordingly, the electrical conductor may be a high-power electric conductor of a high-power electric system. In a high-power electric system, conductors may be spaced apart and/or isolated from each other with greater distances than what is possible e.g. in an electrical motor. This distance is referred to as a safety clearance and the size of it depends on the voltage differences in the system. Thus, when depending on air as isolator between an otherwise non-isolated busbar/conductor and another conductor or structure of conductive material such as a metal cabinet, the distances must be taken into account in compliance with safety regulations. It should be mentioned that air quality/pollution degree, such as humidity and particle content, may also be relevant for the distance of the safety clearance. In case a conductor is used in a high-voltage system the surface is manufactured to reduce field concentrations.

Further, the cross-sectional area of a current path through a conductor according to the present invention is larger than the cross-sectional area of e.g. a winding of an electric motor. This may be true both with respect to a cross-sectional area at a given point of the conductor and over a distance of e.g. 20 cm or 30 cm in the longitudinal direction of the conductor and physical dimensions.

Current conducting busbars of a high-power installation or system is typically fastened to a structure comprising the system for every 25-35 cm. If the current is conducted by cables, the distance between cable fasteners may be even smaller. The fastening may be made by screwing bolts into a support structure such as an electric cabinet or by screwing clamps to the support structure which is then closed and thereby fastening the cable/busbar. The conducting cables/busbars are of course insulated from the support structure.

In such high-power installations where the primary aim of conductors is to distribute electric energy to components, the magnetic field around a conductor of the present invention is not as important as it is e.g. around a winding of an electrical motor. Thus, since the magnetic field is not the main purpose for manufacturing the electrical conductor for a high-power installation the conductor is typically not designed to have a certain magnetic field when conducting current.

Further, again comparing to e.g. a winding of an electrical motor, a conductor of the present invention would as a general rule be designed with a surface area that is as large as possible to optimize the possible advantages of the invention as described herein. Depending on the purpose of the conductor, the surface may for example be designed for conducting current, conducting current and heat dissipation or heat dissipation. Thus, even though all portions of a conductor of the invention may comprise an electric conductive material, not all portions are necessarily used for conducting current through the conductor. In general, the available area around a conductor is exploited to expand the surface of the conductor for one of, for example, the heat dissipation or current conducting purposes, or other described purposes such as improved flexibility, reduced material consumption, air guidance, etc. The available area is limited by safety clearances to other conductors of different phases having different voltage levels, grounded structures such as elements of an electric cabinet, etc.

An example of a portion of a conductor that is primarily used for non-conducting purposes such as heat dissipation or air guidance, is an outgrowth from the surface of the conductor which is not connected at the distal end of where it is growing from the surface of the conductor. Such outgrowth or protrusion may for heat dissipation purposes preferably comprise some kind of bionic design with airgaps between branches, possibly with a continuous surface towards a direction of air flow for air guidance purposes. Such portions would be referred to as conductor branches if these were part of the middle segment conducting current form one end to the other. Such outgrowth may in principle take any form or geometry exploiting the free space around the area as long as safety clearance distances are maintained. In such examples, the fraction of current conducted by the surface area of the outgrowing conductor portion is very small if not zero.

An example of a portion of a conductor that is only used for conducting a current may in principle not be possible in that heat dissipates even from a solid block and a planar surface. What should be understood by a portion of a conductor primarily used for conducting current, is a varying structure or geometry for a middle segment of the conductor between the first and second terminals. When space is narrowed between components in an electrical system, if other conductors are to be passed, if the conductor has to pass through a current sensor or bushing, etc., the surface area of that particular portion of a conductor middle segment may be reduced to comply with available space, thereby typically increasing the conductor density to achieve a narrower outer dimension. In this example, at this particular portion of the conductor, the current conducting portion of the surface area of the conductor becomes high; possibly so high that a hot spot is created where additional cooling is required to continue to maintain a certain current conduction capacity. Hence, this is an example which may benefit from a combination of the conducting portion with an outgrowth portion, as described above, e.g. on each side of the narrowed part of the conductor. In this way, heat generated at the narrow space can be dissipated via the nearby outgrowths, e.g. further in combination with internal cooling channels.

An example of a portion of a conductor that is used for both heat dissipation and current conduction is a middle part between the terminals, with an airy design or geometry. In such example, the surface areas having the main purpose of dissipating heat and conducting current, respectively, may be the same or close to be the same. This is due to a geometry comprising conductor branches spaced apart from each other so that a flow of cooling air may pass freely by each conductor branch, i.e., through air gaps defined by the conductor branches. In this example the current conducting surface area is large compared to traditional conductors/busbars and windings e.g. of an electric motor. Another difference between a motor winding and a conductor of the present may be found in the circumference of the conductor. The limited space inside a motor obviously limits the circumference of the winding. This is not the case to the same extent e.g. in an electrical cabinet comprising a conductor of the present invention. More space is available and thus the circumference can be made larger leading to an airy design with airgaps for increased cooling. Further, the cross-sectional area of the individual conductor branches of a conductor according to the present invention is often lower than the cross-sectional area of a motor winding.

As mentioned, the electrical conductor 1 may comprise first and second ends 2, 3 spaced apart by a middle segment 4. One complete or final electrical conductor may comprise a plurality of interconnected electrical conductors 1 of the types illustrated/described above. In such embodiment the illustrated electrical conductors may be used as sections of the final or complete electrical conductor. Thus, a final or complete electrical conductor may comprise first and second ends 2, 3, with a plurality of first and second terminals 7, 8 at the ends or between them, e.g. with terminal holes 10 for connecting a plurality of the illustrated/described electrical conductors to form the final or complete electrical conductor.

The terminals 7, 8 may comprise one or more terminal holes 10 or other structures for connecting the electrical conductor 1 to other electrical conductors such as busbars, cables or the above-described electrical conductors, electrical components such as breakers, power modules, batteries, etc.

Alternatively, in an embodiment, one or both of the terminals 7, 8 of the electrical conductor 1 form part of an electrical component as an alternative to being provided as freely connectable locations at the conductor 1.

A terminal 7, 8 may in a simple embodiment comprise a terminal hole 10 through the terminal 7, 8. Via such hole, a bolt can go through and continue through a component with which the electrical conductor 1 is to be connected. The electrical conductor and the component are then clamped together via a nut and the bolt.

Alternatively, a terminal 7, 8 may be a click terminal that is either designed to receive a click part form a component to which the electrical conductor is the be connected or designed with a click part that is to be inserted into such other components.

Alternatively, a terminal 7, 8 at an end 2, 3 of the electrical conductor may be manufactured with a threat which when engaging with a bolt is able to assist in clamping a component to the electrical conductor 1.

Further, it should be noted, that an electrical conductor as illustrated or a complete electrical conductor comprising a plurality of electrical conductors such as the above described may have more than one first end 2 or more than one second end 3. Hence, one end of an electrical conductor 1 may branch off in e.g. three terminals each with a terminal hole. This may be advantageous in that the geometry of the electrical conductor is then designed specifically to the component to which it is to be connected. Branching off the ends into several terminals may also improve heat dissipation capacity at the possibly denser terminal portions, improve electrical connection between the conductor and components, and avoid additional connection pieces or shunts in order to connect adjacent components to a common conductor.

The middle segment 4 may comprise one, but preferably a plurality of conductor branches 5. The conductor branches 5, like the end segments 2, 3, are at least partly made of an electric conductive material such as copper or aluminium or alloys thereof, enabling the electrical conductor 1 to conduct a current between its terminals 7, 8. The design of the conductor branch(es) 5 may be optimized according to a specific purpose such as cooling, material consumption, flexibility (control in a particular direction), footprint, etc. Thus, depending on which parameter(s) the electrical conductor 1 is designed according to, the conductor branches may be designed as longitudinal cylinders (or other geometries such as oval, square, etc.), web, bionic, gyroid-like design, lattice-like design, branch-like design, or sponge-like design, coil or solenoidal designs, spirals, etc.

Thus, the electrical conductor may have a perforated surface, a non-perforated surface, a massive structure or a structure with internal channels optimizing the electrical conductor according to skin-effect and cooling, etc.

Two or more conductor branches 5 may meet in an intersection point 9 and two or more conductor branches 5 may branch off from an intersection point 9. This has the effect, that an electrical conductor is established that maintain a desired strength (determined yield point) with a minimum of material. Among others, this may reduce the cost of the electrically conductive material and reduce the weight of the conductor. It should be mentioned that two conductor branches meeting in the intersection point 9 may be the same two conductor branches leaving that intersection point 9. Alternatively, two other conductor branches may leave the intersection point, however this may be a question of definition of a conductor branch. Further one conductor branch may branch off to a plurality of conductor branches and a plurality of conductor branches may meet and form a lower number of conductor branches.

Further, it should be mentioned that the electrical conductor 1 may be designed as a plurality of electrical conductors, e.g. as a combination of three phase conductors or as a wire harness or printed circuit board traces of a printed circuit board used for mounting in an electric panel.

At least a first end 2 and a middle segment 4, but preferably also the second end 3, of the electrical conductor 1 of the present invention are monolithically formed, since they are manufacturing from a single bulk of material, which is machined to provide the electrical conductor 1. Here bulk of material should be understood as the material such as electrically conductive material of which the electrical conductor 1 is made, e.g. a solid, powder, liquid, wire, etc. Here machined should be understood as manufactured by additive manufacturing, i.e. the electrical conductor 1 is made in one piece without any mechanical connections of the first end 2, second end 3 and middle segment 4.

Note that more than one type of material, e.g. two bulks of material, may be used to manufacture the electrical conductor. One of such two or more bulks of material may be electrically non-conductive.

Note that in some embodiments it may be necessary to manufacture the electrical conductor in more than one piece. In this situation the electrical conductor may be referred to as a complete or final electrical conductor which comprises a plurality of electrical conductors 1 as described above. This may be the case e.g. if the electrical conductor needs to be mounted in a location where it cannot be inserted unless the electrical conductor is separated in two or more pieces or if the complete electrical conductor has to be larger than what is possible to manufacture by additive manufacturing. In such situation, terminals of two electrical conductors are connected, extending the length of the middle section and thereby the current path between the first end 2 and the second end 3 and thus of the complete electrical conductor. Such connection may be prepared by designing terminal holes in the conductor where, e.g., fish plates or other joints may be fastened and thereby connecting the two middle segments.

It should be noted that the electrical conductor 1 may have a non-uniform geometry/design. The design/geometry may take any machinable/printable shape. Such shape may be optimized according to conducting current (skin effect), cooling, guidance of flow of cooling fluid, other components in a panel, resistance, power loss or current displacements, etc.

In a particular embodiment, the electrical conductor 1 may have a non-uniform diameter (measured in a transversal direction) along the lengthwise direction. A well-defined diameter may nevertheless be determined e.g. at a transversal plane at which that electrical conductor 1 has its smallest diameter.

Moreover, in an embodiment of the invention the perimeter length of the electrical conductor 1 or its conductor branch(es) 5 may vary in transversal planes at different positions in the lengthwise direction of the electrical conductor 1. The perimeter length of a given part of the middle segment may simply be measured as the sum of all lengths of perimeters of branches in a given transversal plane. Hence, the perimeter length at a given part may thus be the length of the perimeter of conductor branches measured across/perpendicular to the longitudinal direction of the electrical conductor at that part. A part of a conductor may also be referred to as a portion of a conductor and should be understood as a reference to a specific portion of the conductor such as an end or middle segment.

The perimeter length of the conductor branches 5 may be the sum of lengths of perimeters of all individual conductor branches 5. As one conductor branch may split from a stem to two or more twigs, i.e. branches of a branch, the perimeter at one part of the conductor branch may be different from one part (e.g. a twig part) to another part (e.g. a stem part). Hence, the sum of lengths of perimeters of the conductor branches may be the sum of all individual twigs or of all the individual stems. In case of multiple different possible perimeter lengths for the conductor parts along the length of the electrical conductor, the smallest perimeter length may preferably be used in calculation of current conduction capability of the electrical conductor 1.

In the same way, the cross-sectional area of an electrical conductor at a given part is measured as the sum of the cross-sectional area of all conductor branches at a given part along the length of the electrical conductor. The cross-sections at that part should be measured perpendicular to the longitudinal direction of the electrical conductor.

In an embodiment, the electrical conductor 1 may comprise one or more cooling channels, where the cooling channel may be placed inside the one or more conductor branches, transversally and/or longitudinally.

The manufacturing of the electrical conductor 1 may be done by an additive manufacturing process. Such manufacturing process may be based on, but not limited to, one of the following additive manufacturing processes: 3D printing, layer by layer printing, Wire Arc Additive Manufacturing, Fused Deposition Modeling FDM, Direct Energy Deposition, Direct Metal Deposition, sintering based processes, laser based processes, for example Powder Bed Fusion PBF, such as selective laser melting SLM or selective laser sintering SLS, cold spray additive manufacturing CSAM, binder jetting or binder jet 3D printing, etc. It should be mentioned that the actual additive manufacturing process used to print or build the electrical conductor 1 may not be important as long as the material of which the electrical conductor is built is an electrically conductive material.

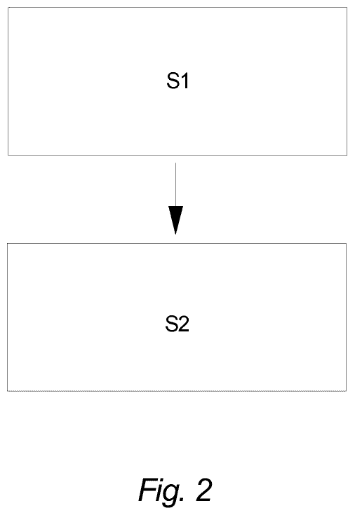

FIG. 2 illustrates method steps for machining an electrical conductor 1 according to an embodiment of the invention. The particular method relates to forming an electrical conductor with two ends or two terminals, namely a first end/terminal and a second end/terminal via a middle segment, but may be used for producing any kind of electrical conductor of the present invention.

It should be mentioned that this may include manufacturing both ends and the middle segment in one process. Hence, with additive manufacturing along the longitudinal direction of the conductor, the method may start by manufacturing, such as printing, one end, then a transition to the middle segment, possibly one or more conductor branches, then the middle segment, then a transition to the second end and finally the second end. In another embodiment, the additive manufacturing occurs transversal to the conductor's longitudinal direction, thereby for example manufacturing portions of both ends and the middle segment simultaneously, increasing the cross section with each applied layer. In another embodiment, the additive manufacturing is radial, or even arbitrary, to the conductor's longitudinal direction, for example using cold spraying CSAM or Fused Deposition Modeling FDM while rotating or freely moving either the conductor unit being built or the nozzle, or both. Preferably, the mentioned segments are manufactured in one process, e.g. as one segment is manufactured, the next segment is being manufactured. A transition part may be made between such two segments which may start or include the first segment. Similarly, the second segment may include a transition part or is connected to such transition part.

It should also be mentioned that the method could in some embodiments comprise manufacturing the middle segment and afterwards connect the end segments. The end segments could be connected while being additive manufactured or could be connected with an additive manufacturing thermal paste or glue after being made. The end segments could also be welded, glued or connected in any other way to the middle segment, e.g. by cold spraying CSAM.

An additional embodiment of the invention could be a manufacturing method that comprises two or more middle segments being additive manufactured. The two or more middle segments could be additive manufactured in the same process with the two end segments to form the electrical conductor. The two or more middle segments could also be additive manufactured separately and connected afterwards to form the electrical conductor.

The two or more middle segments could be identical or could be two differently shaped or otherwise characterized middle segments depending on where the electrical conductor should be placed in e.g., an electrical cabinet.

A transition may straightforwardly be defined as a change of size of a layer compared to a previous layer. In this way a transition may be formed as a perpendicular transition between an end segment and a conductor branch of the middle segment. Alternative, subsequent layers may change in cross-sectional area and thus form a transition as a rounded transition which may be advantageous in terms of a reduced resistance for current conducted between the ends of the electrical conductor.

A monolithic conductor according to the present invention is made from one material. One or more additional materials may be used e.g. as isolation, for heat dissipation, etc. in this case the conductor may be referred to as a polylithic conductor. No matter the number of materials, a conductor produced by additive manufacturing is produced bit-by-bit starting at a first spatial coordinate (x, y, z) and ending at a second spatial coordinate. At least when the conductor is finished the first and second spatial coordinates are electrically/mechanically connected. As mentioned several methods of manufacturing a conductor exists all including some kind of material depositing, joining or soldering to manufacture a conductor in one monolithic form.

In this document a conductor may be referred to as being manufactured layer-by-layer no matter the additive manufacturing method used. Hence, if a conductor is sliced (no matter in which orientation) and one is looking at the cross-section of the conductor it is easy to imagen that the conductor is manufactured starting with material in first point, then with material in a second point and so on. Since the conductor is volumetric i.e. has a three dimensional geometry the first point is different from the second and subsequent points at least in one of the spatial X, Y and Z directions/plans. Thus, with reference to the spatial X, Y and Z planes a conductor could be said to be built from a plurality of subsequent layers even though when manufactured all material in one plane such as X=1 and Y=0 and Z=0 is not provided as a one layer or in one layer before material in a next layer (e.g. an X=2 layer) is provided.

Hence, no matter which of the processes of manufacturing a three-dimensional object such as a conductor that is used, it can be said that the conductor is manufactured layer-by-layer even though some of these manufacturing processes are based on deposited, joined or solidified with material being added together in areas, lines, pointwise, etc. This is because no matter the additive manufacturing process the conductor is manufactured one point after the other. A plurality of points in the same plan (e.g. X=3) is considered one layer also if they are not physically connected in this plane. And when all points of this layer are added, points of the next layer (e.g. X=4) is added to the points in the X=3 layer. As mentioned, a layer may be defined in any of the planes of a spatial Cartesian coordinate system.

Alternatively, the ends may be separate segments that are connected via the middle segment. The middle segment may be printed, and during the manufacturing of the middle segment it may be attached to the ends such as printed, heated, glued or the like onto the ends. The middle segment may be joined to the ends by means of welding, printing, soldering, etc.

It should be noted that the ends may comprise terminals for connecting the electrical conductor to other electric parts/conductors/windings of an electric system. Such terminals may be manufactured like the rest of the electrical conductor by additive manufacturing i.e. monolithically formed with the ends.

In a step S1 of this particular method, considering additively manufacturing a conductor in its longitudinal direction from the first end towards the second end, the first end segment and middle segment in the form of conductor branches of a plurality of conductor branches are monolithically formed via individual transitions that may or may not include rounded connections to shape concavely rounded interior corners between the first end segment and conductor branches of the plurality of conductor branches and to spatially separate conductor branches of said plurality of conductor branches.

The step of monolithically forming the first end segment and conductor branches may be implemented using various methods, for example methods such as additive manufacturing such as 3D printing, casting, and simply removing of material, via machining, from a bulk metal slab to form conductor branches combined with a first end segment.

More specific, a known massive conductor such as a main busbar with a length of e.g. 3-5 m may conduct 1-2 A per mm². If the same busbar was made in an airy design and e.g. with an internal cooling, then due to the improved cooling the same 1-2 A per mm² may be conducted with the same efficiency despite the removal of material. Typical conductor materials such as aluminium and copper have temperature coefficients at approximately 0.4%/deg C. If such conductor is efficiently cooled so that the temperature is e.g. 25 deg C lower compared to a conventional conductor, the resistance is reduced by approximately 10%. Hence approximately 10% of the material can be removed without compromising the losses. Furthermore, in AC conductors the current is not evenly distributed across the conductor volume. Typically, the current density is reduced towards the center of the conductor. Taking such considerations into account can allow for further removal of material without compromising the efficiency of the conductor.

In a step S2 of the method, the first end segment becomes electrically coupled and mechanically coupled to a second end segment via the middle segment of the electrical conductor formed by the plurality of conductor branches. This may also be monolithically achieved, e.g. by continuing the additive manufacturing, as described in step S1.

The coupling of the end segments to the middle segment could also be done by welding, gluing, male/female locking mechanism or any other way that would connect the segments both mechanically and electrically.

An optional, additional step of the method of manufacturing the conductor of the invention comprises a step prior to the step of additive manufacturing any of the first, second or middle segments. The step prior to manufacturing the electrical conductor is a step where a digital representation of the electrical conductor is designed in a software program, e.g. a 3D CAD software. The step of designing the digital representation of electrical conductor in a software program includes taking the electrical, mechanical, structural, geometry and other aspects of the physical electrical conductor into account. Thus, based on these inputs, e.g. provided by a user of the 3D CAD software, a digital representation of the conductor is provided by the 3D CAD software. When the digital representation of the electrical conductor is complete the additive manufacturing process can be started.

A further optional step may be applied i.e. a heat treatment to the finalized conductor. A heat treatment may e.g. be 4 hours at 400 C and upwards depending on the material. An advantage of heat treatment is that the particles of the manufactured conductor is mutual positioning or merging leading to higher conductivity both thermal and electrical. This is at least true for Aheadd® CP1 20/63 aluminium powders and other aluminium-iron-zirconium powder solutions. Such powders may be used in laser powder bed fusion machineries. Using this type of powder and heat treatment may lead to higher thermal stability, thermal conductivity, corrosion performance and surface finishing as well as higher electrical conductivity.

The middle segment may in principle have any design/geometry, for example providing flexibility thereto allowing the electrical conductor to deform. It may be formed by conductor branches being solid or having internal cavities to reduce the amount of material that is needed to manufacture the electrical conductor. It may be formed by a web or as a hybrid between conductor branches or web just to mention a few possible designs.

Internal cavities may be used as cooling channels and/or additional surface for conducting high frequency current. Accordingly, the end segments and middle segments may be designed for the particular panel/electric system in which it is used, for a particular type of current to conduct, for having a desired or dual functionality, etc.

One such functionality, beside the above-mentioned may be as a structural support. Hence, if needed the electrical conductor may be designed to assist in carrying the weight of electric components connected thereto. Hence, its dimensions may be larger than what is needed by it for carrying the required current. Similarly, its geometry may be designed for the combined purpose of mechanical support and electric conductance. This is especially true if such support is flexible/deformable in that it may both assist in supporting and at the same time assist in absorbing vibrations.

It should be mentioned that the electrical conductor 1 may be manufactured in two or more resolutions. The thicker layer the faster manufacturing. The layer thickness depend on the material and printing apparatus and may vary from a few millimetres to 20 um, using some combinations the layer thickness is between 50 um and 150 um. In case of additive manufacturing resolution may be defined by thickness of the layers of which the electrical conductor is built (another word for machined and processed). A first resolution that is finer i.e. having thinner layer size than a second resolution may be used when manufacturing the interface between the electrical conductor and the part to which it is connected. Such interface may be the part of the terminal that is in contact with the other part. Alternatively, resolution may be determined by material deposition rate, material flow rate, etc. depending on the type of additive manufacturing used.

To avoid electric losses in connections between two electrical conductors it is preferred that the two parts have mating surfaces, which is most simply achieved by having planar surfaces, but may also be achieved by convex and concave combinations, mortise or finger joints, engaging teeth, cylinder and peg, tongue and groove, slide lock, etc., to further achieve additional advantages, e.g. larger surface area of connection, easier assembly of electrical conductors such as busbars in electrical systems by self-locking, etc., as long as good electrical connection is prioritized. The finer these interfaces are manufactured the better/the less post manufacturing processing is needed to ensure sufficiently mating surfaces, such as planar surfaces.

The second resolution manufactured e.g. with thicker layers would be more rough leading to more surface area. At least for middle and high frequency currents this may lead to conductance of more current without increasing the need for material/dimensions of the conductor. In fact, the middle segment may be manufactured intentionally with a corrugated surface to increase the current-carrying outer surface of the electrical conductor (current-carrying with medium and high frequencies) because of more efficient cooling due to the turbulence of, e.g., cooling air flow created due to the corrugated surface. It should be noted, that if the conductor includes an interior space, the inner surface of the conductors creating such interior space may also be corrugated for the same purpose. A corrugated surface has the effect, apart from offering a larger surface area, that it introduces turbulence in the flow of cooling fluid such as air. Increased speed of cooling fluid may lead to higher cooling effect.

As an example, the depth into the conductor which is used for conducting current at medium and high frequencies may in a specific embodiment be approximate 1.5 mm. In this specific example, the conductor is made of copper with a resistivity of approximate 1.68 μΩ cm, a relative permeability of approximate 1 at a frequency of 2 kHz. Thus, a conductor for this particular embodiment may be hollow having conductor thickness of 2 times 1.5 mm. In practice such conductor may be manufactured with a thickness of 4-5 mm leaving room for a cooling in the interior or simple reduction of conductor material and thereby weight.

Knowing that skin effect also appears at e.g. 50 Hz, a reference to a medium frequency with respect to skin effect is a reference to frequency starting around 500 Hz where the design of the conductor may account for the skin effect. The medium frequency range may be between 500 Hz and 10 kHz, above 10 kHz may be referred to as high frequency where skin effect is a fact (the higher frequency, the closer to the surface the current will be conducted).

Further, it should be mentioned that the outer surface may also be corrugated or designed with fins for increasing heat dissipation from the electrical conductor.

The electrical conductor resulting from the method may be used as an electrical conductor of an electrical installation. The electrical installation may be an electric panel which may be part of a renewable energy facility such as a wind turbine, solar system, grid, substation, etc. The electrical installation or system in which the electrical conductor is used may be an electric vehicle, battery system, power to x facility, ship or other minor or larger electric systems. Further, an electrical conductor resulting from the method can be used inside an electric panel, i.e. in a cabinet/enclosure, or outside such panel, it can be used to connect separated panels, etc.

A variant of an electrical conductor according to the present invention is connected to a traditional cable or busbar. In such embodiment, a traditional busbar e.g. in the back of an electric panel or a traditional cable e.g. between two electric panels may be connected to an electrical conductor of the invention. In this way a traditional cable or busbar may be connected to a component via a conductor according to the invention. Thereby, an easy connection is facilitated due to the flexibility of the electrical conductor of the invention.

However, note that manufacturing the electrical conductor, and thus accomplishing the electrical and mechanical coupling between the first end segment and the second end segment, is typically performed prior to installing the electrical conductor in the electrical installation, and prior to installing the electrical installation in the renewable energy facility. Thus, according to typical embodiments of the invention, the electrical and mechanical coupling is performed prior to installation/integration of the electrical conductor. Nevertheless, methods according to the invention are not necessarily restricted to a particular sequence of steps. Further, various methods according to the invention may comprise additional steps, such as performing digital geometry optimization, additively manufacturing the electrical conductor, and conducting current.

Summing up, a designer is designing a digital representation of the conductor according to electrical, mechanical, structural, etc. requirements in e.g. a 3D CAD software such as Solidworks. Files (digital representation) from such 3D developing tool is exported to e.g. a 3D printer, where the conductor is printed according to the CAD files.

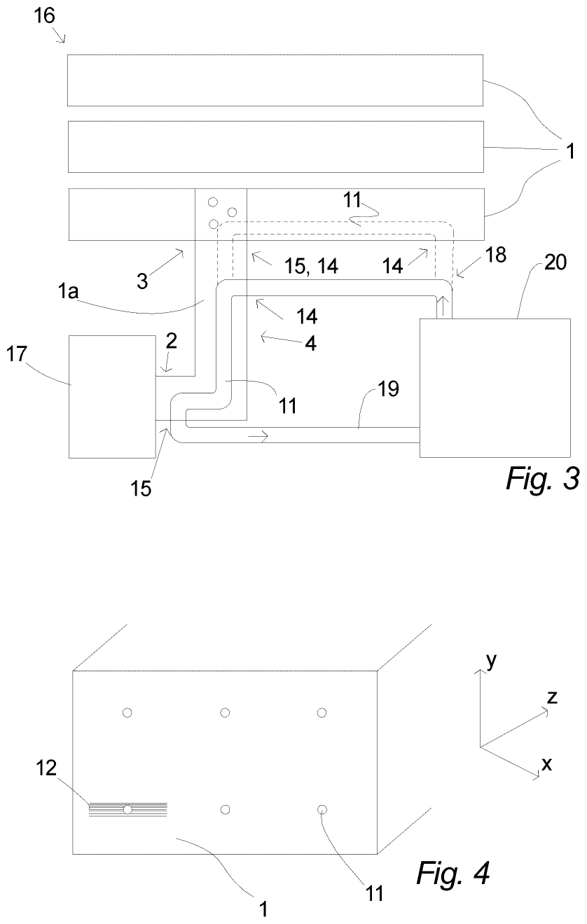

As mentioned above, FIG. 1a-1c illustrate various embodiments of an electrical conductor 1 in which an internal channel 11 according to the present invention can be found or manufactured. FIG. 3 illustrates in more details a high-power electrical system 16 in which a plurality of electrical conductors 1 are used to distribute electric power.

Three parallel busbars 1 are illustrated which may be referred to as main busbars. This is because each of these busbars 1 may supply power to components of the system such as heat generating electrical components 17. The three main busbars may provide a three phased power supply to components even though only one connection/transition busbar 1a is illustrated as connecting one of the main busbars with the component 17.

The transition busbar 1a is connected to the component 17 in the first end 2 and to a main busbar 1 in the second end 3. In the middle segment 4 of the transition busbar 1a an internal channel 11 is illustrated. In this particular embodiment, the internal channel 11 is connected to a heat exchanger 20 via a temperature regulation loop 19. Together, the internal channel 11, regulation loop 19 and heat exchanger 20 may be referred to as a temperature regulation system 18. Such system 18 may include dedicated controllers, valves, sensors, etc. that is needed for such system to work as desired.

The temperature regulation system 18 and the heat exchanger 20 there off may comprise non-illustrated regulations loops. Such additional regulation loops may be used to regulated temperature of electric components such as power modules or ambient temperature e.g. in an electric cabinet.

It should be mentioned that the heat removed from the conductor by the temperature regulation system may be reused to regulate temperature of mechanic or electric components or ambient temperature of an electric cabinet. Accordingly, the heat or cooling of the electrical conductor may be transferred from the coolant of the internal channel 11 via a regulation loop 19 to a non-illustrated component.

The heat generating component 17 may e.g. be a reactor, a power module comprising semiconductor switches, a transformer, contactor, etc. With this said heat it generated to some extent in almost every electrical component in a high-power electrical system 16 including the busbars. Thus, having internal cooling substituting known air cooling of the surface of a busbar lead to a better temperature regulation of the electrical system 16. It should be noted that a conductor 1 may combine an internal channel 19 with an airy outer design e.g., such as those described in relation to FIG. 1a-1c and in this way the cooling of the conductor may be increased.

As an example, connections of two busbars, busbars and components, cables and busbars, etc. may lead to hot spots due to resistance in the connections. Accordingly, if possible, also the ends 2, 3 of the conductor 1 or where the terminal holes 10 of a conductor are located is provided with internal cooling channels 11, in this case, as close thereto as possible. In this way it is ensured to remove heat as close to the source as possible to avoid a general temperature increase of the system 16.

The internal channel 11 is preferably formed during manufacturing of the conductor 1. Hence, the channel 11 is formed when the conductor is manufactured layer by layer by leaving out part of a layer 12. In this way, a cavity forming the channel 11 may be established. It should be noted that the channel 11 may extend through the transition between middle segment 4 and end 2, 3 and thus begin and/or end at one of these ends 2, 3. Only part of the layers 12 needed to illustrated a channel formed in the layers 12 are illustrated.

The channel inlet 14 and outlet 15 may e.g. be formed as or with a channel extension 21. Hence, as the conductor 1 is manufactured, the inlet and/or outlet may also be manufactured. In this way the fluid connections to the channel 11 by the loop 19 is easy to establish simply by a providing a loop pipe over the extension and e.g. in addition provide a hose clamp around the pipe. Such extension 21 may be designed in any desired relevant way and thus be relatively long for it to end at a desired location. Such desired location may be desired e.g. with respect to service and maintenance, mounting, etc.

Alternatively, the inlet 14 and/or outlet 15 may be manufactured as a threaded part. Such threaded part may comprise a thread inside the conductor 1 i.e. the outer most part of the channel 11 is a threaded part. Alternatively, the threaded part may extend from the surface of the conductor 1. Such threaded parts may provide a good connection between a pipe constituting at least part of the loop 19 which may be screwed to such thread by a union nut. Hence, the inlet 14/outlet 15 may be connected to the pipe of the loop 19 in different ways including the above mentioned. Examples of temperature regulation systems (cooling and heating) are provided below.

FIG. 4 illustrates a cross-sectional view of a busbar 1 according to the present invention. The cross-sectional view may be of a middle segment 4 of the busbar 1 and illustrates, in this example, six internal channels. The number of channels is matched with the design of the busbar 1 to ensure that the temperature is as desired when a given current is conducted through the busbar 1.

As indicated by the section of layers 12 illustrated, the channels 11 are formed by the layers 12 forming the busbar 1. The inner surface may have a structure that is designed for a given purpose. Such purpose may be to optimize flow of fluid i.e. a smooth surface may lead to a high flow which may be desirable. Another purpose may lead to a rough surface of the inner wall. This may be desired if e.g., an insulating material has to be attached to the inner wall to give more freedom in choice of fluid to be guided. A rough inner surface wall may also lead to turbulence in the guided fluid which may lead to an optimized cooling. In fact, the wall may comprise outgrows from the inner wall to form flow guides as described below in relation to FIG. 7.

Preferably, a channel 11 extends through the conductor 1 in the same plane (or layers) such as in the same X or Y plane. In this way, the channel(s) obstruct the current path through the conductor as little as possible. What is working, but may not be preferred is a channel that extends diagonal i.e. the layers in which the channel is formed is changing.

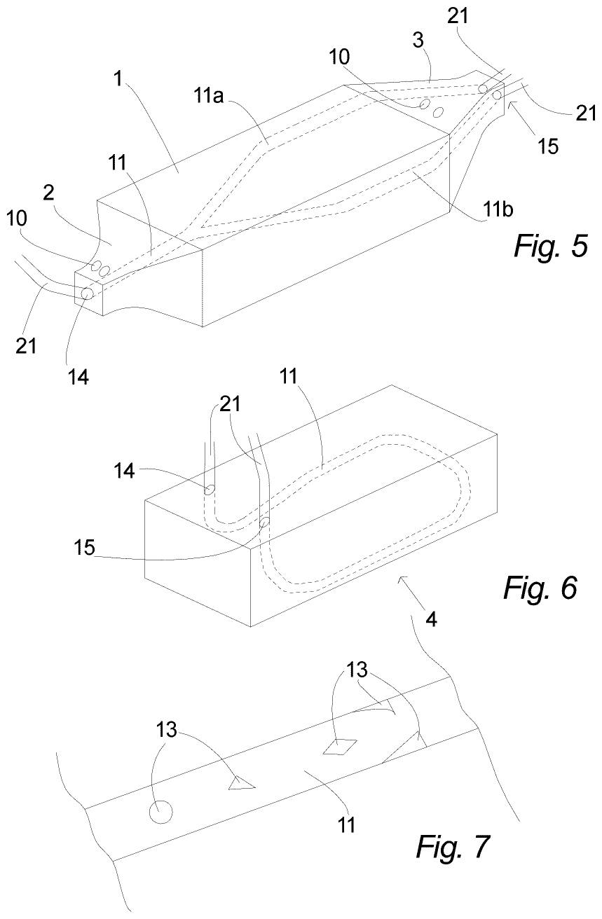

FIG. 5 illustrates a conductor 1 comprising a middle segment 4 and a first and second ends 2, 3 according to the present invention. In this particular embodiment, the middle segment 4 comprises a channel 11 that is branching off in two internal channel branches 11a, 11b. In addition, the middle segment comprises a single channel extension 21 the first end 2 and a double channel 21 extension in the second end 3. This is to illustrated the that the geometry of the design of the conductor 1 may be tailored to the system 16 in which it is used.

This particular design has a high flow of fluid in the extension 21 and channel 11 at the first end and a lower flow in the two branches 11a, 11b. Further, the extensions 21 are in the first end between terminal holes 10 and in the second end 3 the terminal holes are between the extensions.

FIG. 6 illustrates part of a middle segment 4 of a conductor according to the present invention i.e., no ends are illustrated. The illustrated internal channel 11 may have inlet 14 and outlet 15 of the channel 11 is in the same end of the middle segment which may be advantageous in terms of layout/foot of the electrical system 16 and or regulation system 18. The channel 11 thus guide a fluid from a first end towards a second end and back again towards the first end. The inlet/outlet may end in channel extensions 21 as illustrated.

The inlet/outlet 14, 15 may alternatively or in addition extend anywhere from the middle segment 4. Accordingly, the introduction of fluid and the guiding of the fluid inside the conductor i.e. in the channel 11 may be designed to the particular need of the conductor 1. Such needs may be related to peak cooling capacity, layout of one or more channels 11, hot/cold spots, temperature of the fluid entering the channel 11, etc.

FIG. 7 illustrates non-limiting examples of flow guides 13 inside the channel 11. The flow guides 13 may have different geometry depending on the desired turbulence of the fluid guided in the channel 11. Such geometries may include diamonds, cylinders, triangular shapes, ramps, etc. More than one flow guide may be located strategic in the channel 11 in order to increase or maintain turbulence/swirling effects in the fluid flow.

It should be noted that the internal channel 11 described above may be equipped with a pipe such as a replaceable pipe extending through out the channel 11. In this embodiment, the fluid is not directly in touch with inner walls of the channel 11. Instead, the fluid is guided by the pipe, where the pipe is run through the channel 11 after the conductor 1 with channel 11 is manufactured.

Such pipe may be replaced if needed and is advantageous in that clocking of the channel 11 can be avoided as well as no wear of the inner wall of the conductor is happening caused by the flow of fluid. Further, the loop 19 can be made in one pipe without any joints which reduces or eliminates the risk of leakages at the joints between the channel 11 and loop 19 where no pipe runs through the channel 11.

It should be mentioned that the cooling loop may include more than one channel 11. Thus, channels 11 of two conductors 1 may be connected with a pipe or hose of a non-conductive material. The outlet 15 of one conductor may be fluidly connected to the inlet 14 of another conductor and in this way establish a loop 19 which includes a plurality of channel 11 of one or more conductors 1. If the hose is of a non-conductive material in principle, the busbars may not need to be of the same phase. In this case it may be preferred to have a fluid circulated in the hoses which is non-conductive.

Thus, a cooling loop 19 may comprise a first manifold supplying two or more channels 11 with a flow of cooling fluid and a second manifold collecting fluid from the two or more channels 11 to guide it to a heat exchanging part of the cooling system 18.

Further it should be mentioned that the same cooling system 18 may comprise several cooling loops 19 each including zero, one or more internal channels 11.

In one embodiment, the temperature regulation system 18 is conducting a cooling fluid through the internal channel 11 which in this embodiment may be referred to as an internal cooling channel.

The temperature regulation system 18 may comprise a heat exchanger 20 which may by a conventional heat exchanger working based on well known principles. Thus, the cooling fluid circulated in the loop 19 may be heated as it passes through the internal channel 11 and subsequently exchange heat in the heat exchanger 20 e.g. with another fluid of another loop or with a fluid such as air.

Alternatively, the regulation system 18 may comprise a heat pump. Such heat pump may also work according to well-known principles such as pumping a liquid into the channel 11 where it evaporates and returns as a gas to the pump/compressor. Here the pressure of the fluid is increased and heat as consequence hereof is exchanged with surroundings before it is introduced into the channel 11 again.

A liquid cooling fluid is preferred over e.g. a flow of air in that the heated liquid can be transported out of the electrical system 16 either directly or via some kind of heat exchange. A liquid cooling fluid may be a phase changing cooling fluid that at least partly changes phase in at least part of the cooling loop 19. A broad variety of cooling fluids may be chosen such as carbon dioxide, R32, R410A, etc.

Even though referred to as a cooling system and internal cooling channel, depending delta temperature between conductor 1 with channel 11 and cooling fluid, may also provide heat to the conductor 1 via the channel 11.

This delta temperature may be controlled by a controller of the temperature regulation system 18 which may control the heat pump, flow of cooling fluids in cooling loops, etc. Such control of temperature of cooling fluid circulated in the channel 11 may be made based on input from temperature sensors located inside or outside the electrical system 16 and desired reference temperatures.

Accordingly, without any changes to the regulation system 18, except from maybe an adjustment of a reference temperature, the regulation system may operate as a combined busbar heating and cooling system.

Hence, if heating of the busbar is required e.g. to increase temperature in the electrical system 16, remove condense from the surface of the busbar, etc. e.g. prior to conducting current in the busbar the regulation system 18 may facilitated that. Subsequent, when e.g. power losses increase the temperature of the busbar, then the temperature may be reduced or at least the speed with which the temperature increases may be reduced. Both adding and removing heat may be facilitated by circulating a fluid (referred to as heating or cooling) in the internal channel 11.

It should be mentioned that the fluid may not be the same if heating is required and if cooling is required. A valve may guide different types of fluid into the channel 11 depending on purpose. Thus, the controller of the regulation system 18 may furthermore control valves, flow speed, etc. and thereby properties of the cooling system such as with which type of fluid for cooling or heating that is used.

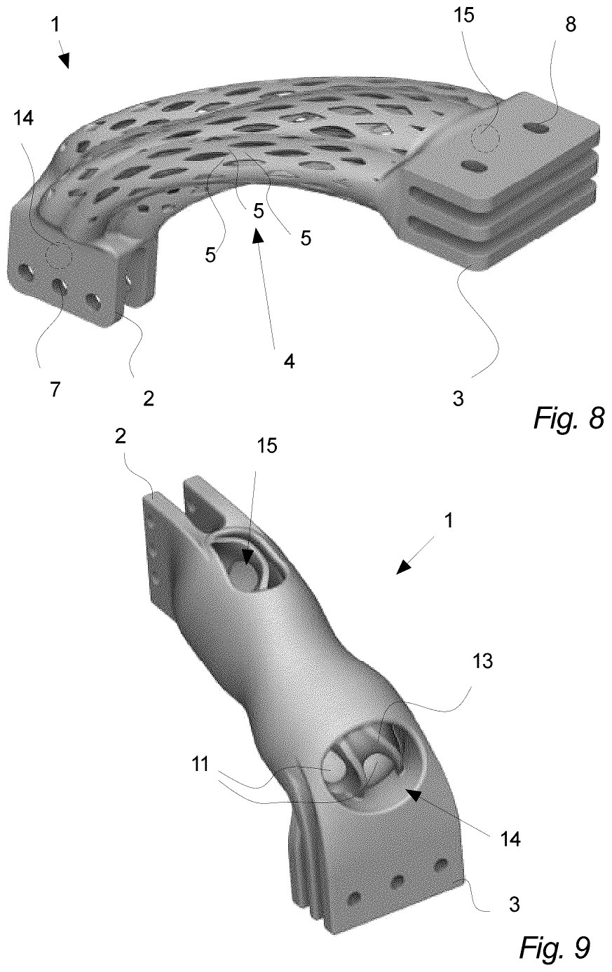

FIG. 8 illustrates an electrical conductor such as e.g. a transition or main busbar having end segments 2, 3 of an U-shaped and E-shaped design. It should be noted that the middle segment of a first conductor towards one or both ends may split and thereby divide the end(s) in two parts. Such split may form a U-shaped end section. Such U-shaped end section together with the middle segment may form a conductor having an Y-shape towards one or both of the ends. This is in FIG. 8 illustrated towards the first end segment 2. Such two parts may then at least partly enclose a middle segment or an end of a second electrical conductor to which the first conductor is to be connected. In this way the split end(s) 2, 3 provide a set of terminal holes 7, 8 allowing a bolt to pass through both holes of the terminal and a through hole in the conductor while fastening the first and second conductors. In an embodiment, the first conductor may be a transition busbar and the second may be a main busbar.

In the same way, the fastening holes may also be implemented e.g. as a U-shaped part of e.g. an end segment or separate fastening segment or area of the busbar.

It should be noted that such alternative end segment design may be shaped in various forms including an E-shape such as the second end segment of FIG. 8 configured to receive and enclose two end segment parts. These may be from one or two different busbars. In fact, at the outer parts of such E-shaped end segment, additional end segments may be connected. Hence, an end segment with an alternative design may facilitate connection of several individual busbars.

Hence, U-shaped and E-shaped end segments may facilitate a sandwich-type connection of end segments of two or more busbars reduction electrical losses in the connection. An alternative connection of end segments could be circular, a triangular, square or multiple angular shaped. When end segment designs with such shapes or geometries are made so that the fit each other such as one can be inserted in the other, the busbars having these end segments can be connected with a turn-and-lock type of fastening. This may include recesses and associated protrusion which interlock the tow end segments when joints and turned or displaces. In addition, a bolt or similar may be provided to ensure the end segments are maintained in the interlocked position.

The middle segment 4 of the illustrated conductor 1 has an outer diamonds pattern and in inner structure. The inner structure may have a diamonds pattern or other patterns i.e. a structure at least partly forming a flow guide. The inner structure may have a closed or solid surface so that a pipe is formed for conducting a fluid. The fluid may be in the gaseous state such as air or other gaseous temperature regulation gases including refrigerants, or it may be in the liquid state such as water or other liquid temperature regulation liquids including coolants.

The inner structure/channel may extend from one of the ends 2, 3 and into the middle segment or from one part of the middle segment 4 into the middle segment. Preferably, the fluid is also leaving the middle segment to establish a temperature regulation circuit 18 (not illustrated in FIG. 8). The internal channel is not possible to see in FIG. 8 but extends behind the outer diamonds structure.

The internal channel may start at the one of the end segments 2, 3 such as between the two parts of the U-shaped first end segment 2 or at channel inlet 14 illustrated by a stipulated line. The internal channel may exit the conductor a the channel outlet 15 at the second end 3.

As mentioned, (and illustrated in FIG. 3) a channel outlet/inlet 14, 15 may also be provided in a middle segment which then connects an internal channel 11 of one conductor with an internal channel of another conductor. One way of implementing this is to establish a channel outlet in the side of the first conductor and a channel inlet in the end segment of the second conductor (as illustrated in FIG. 3 with stipulated lines). In this way, the temperature regulation circuit 18 includes at least two conductors which thereby provide paralleled or series connected loops 19 of the circuit 18.

The conductor of the present invention illustrated in FIG. 8 being manufactured by additive manufacturing may be manufacture as a curved conductor. i.e. no post processing is needed to bend the conductor. The curve is typically 90 degrees as illustrated in FIG. 8 or less, but could in principle be any angle. Such curved conductor may reduce number of connections in a panel and thereby mounting time and also losses in connections conductors.

Further, the conductor of the present invention illustrated in FIG. 8 being manufactured by additive manufacturing may be twisted between 1 degree and 359 degrees. In this way the end segments may be oriented differently and fastened e.g. to other conductors with bolts that are having non-parallel center axis. This is leading to a more flexible design of the layout in a panel and sometimes also easier mounting of the conductors in a panel.

The electric conductor 1 illustrated in FIG. 8 may comprise one first conductor branch 5 that may branch off to a plurality of second conductor branches 5, each of these second conductor branches may further branch off to a plurality of third conductor branches 5 and so on through the middle segment of the electric conductor 1. In this way, following the direction of the current flow through the electric conductor 1 from a first end to a second end, current is allowed to flow in the first conductor branch, then allowed to divide into a flow in the second conductor branches and again allowed to divide into a flow in the third conductor branches and so on into additional n^{th} conductor branches.

In an embodiment, if current is flowing from a first end segment to a second end segment, the first conductor branch may have a first cross-sectional area, the second conductor branches may have a second cross-sectional area which is smaller than the first cross-section area. Following, the third conductor branches may have a cross-sectional area smaller than the second cross-sectional area. Accordingly, the cross-sectional area of the conductor branches may be varied in size in the longitudinal direction of the middle segment.

As described above, the conductor branches of the electric conductor may branch off into a plurality of additional (n^{th}) conductors. In the same way, the conductor branches may also converge from a higher number of conductor branches into a lower number of conductor branches.

It should be mentioned that a cross-sectional area of the middle segment at one distance from a first end segment may be the same as a cross-sectional area of the middle segment at a second distance from the first end segment while the number of conductor branches at the first distance is different from the number of conductor branches at the second distance.

Further, it should be mentioned that the cross-sectional area of the middle segment at the first and second distances from a first end segment may be different while the number of conductor branches may be the same. Of course, the cross-sectional area and the number of conductor branches may also be the same at the first and second distances from the first end segment.

The branching off may be in one plane. This plane may be of a tangent to the surface of an electrical conductor having a curved design. Further note that such branching off may either be at the within the fixed uniformity of the conductor and/or it may be from one conductor to another e.g. via a joint/fixing of two conductors.

It should be mentioned that embodiment of the electrical conductor may also include designs where the conductor branches branch off from the first end segment to a plurality of conductor branches and converge again into the second end segment without branching off between the first and second end segments.

FIG. 9 illustrates another conductor 1 according to an embodiment of the invention comprising an internal channel 11. In fact, this conductor comprises a plurality of internal channels 11. These channels are all connecting an inlet opening 14 and an outlet opening 15. These openings are provided in the outer structure of the conductor via two openings into the conductor interior. The internal channels 11 are divided by walls or flow guides 13 ensuring that a fluid that enters the channel opening is distributed inside the conductor.

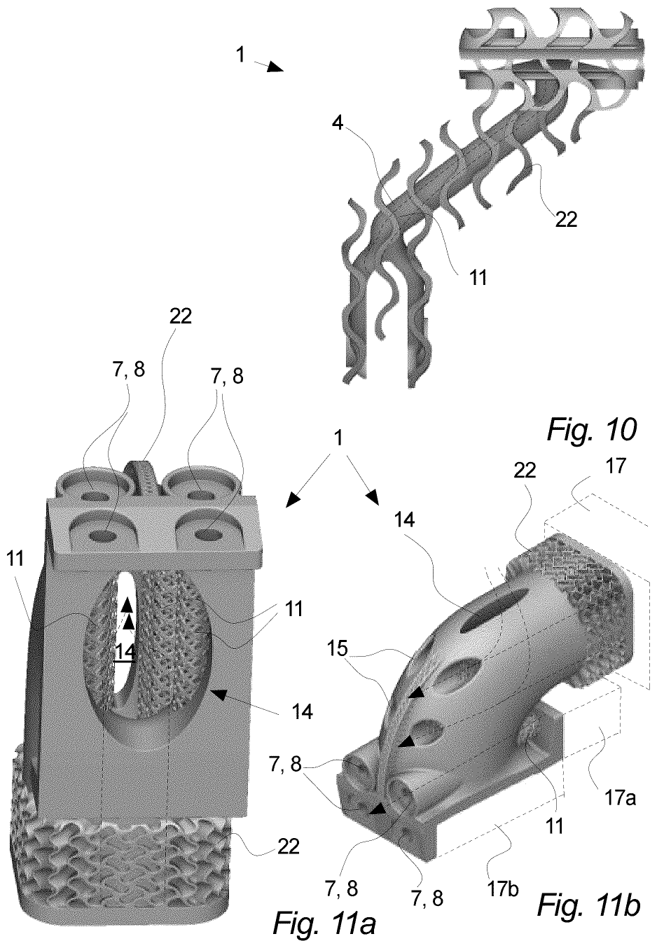

FIG. 10 illustrates a conductor according to an embodiment of the invention. This conductor comprising external heat sinks 22 which may be formed with internal channels. Internal channels of these heat sinks 22 may be connected in series or in parallel forming a cooling loop of a cooling circuit. In the same way as describe above, the middle segment 4 of the conductor 1 may comprise an internal channel 11 (illustrated with stipulated lines) which may be connected to a cooling circuit.

FIG. 11a and 11b illustrates the same conductor from two different angles. This conductor 1 is a connecting or transition conductor that is connected to a heat generating component 17 such as an electrical switch. Heat from the heat generating component may be guided from the end/contact surface of the conductor 1 connected to the switch via the internal channels 11 and out in the open around the conductor 1 through channel outlets 15. Further, a flow of air may be generated or provided through the channel inlet 14 which is assisting the removal of heat from the contact surface. It is noted that the direct of air flow and heat transfer path indicated by the dashed arrows may be the other way especially if air flow is controlled to be so.

Two main busbars may be connected to the conductor 1 via the terminals denoted 7, 8. Hence, as noted the internal channels 11 may also be used as bolt enclosures or guide i.e. when mounted, the internal channel 11 may house a bolt connecting the conductor 1 to a busbar.

Such busbar may also be considered a heat generating component 17. In FIGS. 11a and 11b heat from the upper busbar 17a may also be removed via internal channels 11. More specific the internal channel 11 indicated by the pointer to an outer part of such internal channel denoted 11 at the lower dashed arrow of FIG. 11b. The busbars 17a and 17b is indicated as two busbars but could one.

Note that to optimize heat distribution and heat exchange with surrounding air, the outer surface of the conductor 1 is equipped with heat sinks 22.

From the above it is now clear that the invention relates to a high-power electrical system 16 comprising: a plurality of high-power electrical conductors 1 configured to distribute power in the high-power electrical system in particular to an electrical component. At least one of the plurality of high-power electrical conductors 1 comprising a first end 2 space apart from a second end 3 by a middle segment 4, the middle segment 4 comprises at least one internal channel 11 and one or both of the ends are monolithically formed with the middle segment 4.

In addition, the high-power electrical system 16 may comprise a temperature regulation system 18 comprising a temperature regulation loop which includes the internal channel 11. The regulation system 18 is configured for regulating the temperature of the high-power electrical system 16 by controlling/guiding a fluid through the cooling loop and thus through the internal channel 11.

Thus a temperature control of a high-power electrical system is provided where the temperature regulation is made via a conductor 1 such as a busbar with an internal channel 11. Such busbar with internal channel is able to either cool or heat the busbar 1 and thereby its surroundings. This is done by connecting the channel 11 to a temperature regulating loop 19 of a temperature regulating system 18.

The conductor 1 with internal channel 11 is preferably manufactured by additive manufacturing and may include channel extensions 21 for easy mounting of e.g. a cooling loop 19 to the channel 11. In this way, a temperature regulation of e.g. an electrical panel housing the high-power electrical system is established without the need of installing e.g. additional cooling equipment in the cabinet. Thereby, it is possible to maintain a compact cabinet without additional components that may lead to failure and service.

Such temperature control is efficient in that cooling may be applied at hot spots and thereby capacity of the cooling system can be reduced leading to a cheaper and more compact cabinet.

The invention has been exemplified above with the purpose of illustration rather than limitation with reference to specific embodiments. Details of specific embodiment have been provided in order to understand the aim of the invention. Please note, that detailed descriptions of well-known systems, devices, circuits, and methods have been omitted so as to not obscure the description of the invention with unnecessary details.

### LIST

1. Electrical conductor
   a. Connecting/transition busbar
2. First end
3. Second end
4. Middle segment
5. Conductor branch
   a. Longitudinal conductor branch
   b. Transversal conductor branch
6. Air gap
   a. Longitudinal airgap (in X direction)
   b. Transversal airgap (in Y direction)
   c. Vertical airgap (in Z direction)
7. First terminal
8. Second terminal
9. Intersection point
10. Terminal hole
11. Internal channel
   a, b. Internal channel branch
12. Layers
13. Flow guides
14. Channel inlet
15. Channel outlet
16. High-power electrical system
17. Heat generating electrical component
18. Temperature regulation system
19. Temperature regulation loop
20. Heat exchanger
21. Channel extension
22. 22 Heat sinks

1.-42. (canceled)

43. A high-power electrical system comprising:
a plurality of high-power electrical conductors configured to distribute power in the high-power electrical system, at least one of the plurality of high-power electrical conductors being mechanically and electrically connected to a heat generating electrical component; and
a temperature regulation system including a temperature regulation loop,
wherein at least one of the plurality of high-power electrical conductors includes a first end space apart from a second end by a middle segment,
wherein the middle segment includes at least one internal channel which is included in the temperature regulation loop and is configured to guide a temperature regulating fluid circulated in the temperature regulation loop,
wherein at least one of the first end and the second end is monolithically formed with the middle segment,
wherein the at least one internal channel comprises a channel inlet and a channel outlet, and
wherein the channel inlet and channel outlet are provided in the middle section.

44. The high-power electrical system according to claim 43, wherein the at least one internal channel extend at least one quarter, preferably at least half, most preferably at least three quarters of the longitudinal length of the middle segment.

45. The high-power electrical system according to claim 43, wherein the at least one internal channel is longer than the shortest distance between the two ends of the middle segment.

46. The high-power electrical system according to claim 43, wherein the plurality of high-power electrical conductors comprises at least two, preferably at least three, most preferably at least four internal channels.

47. The high-power electrical system according to claim 43, wherein the at least one internal channel branches off in at least two internal channel branches.

48. The high-power electrical system according to claim 43, wherein the at least one internal channel comprises a plurality of flow guides.

49. The high-power electrical system according to claim 43, wherein the at least one internal channel is monolithically formed with a channel extension.

50. The high-power electrical system according to claim 43, wherein the part of the channel extension is manufactured in the same electrically conductive material as the middle segment or one of the end segments of the electrical conductor.

51. The high-power electrical system according to claim 43, wherein the at least one internal channel is an internal cooling channel connectable to an external cooling loop via a cooling channel inlet and a cooling channel outlet.

52. The high-power electrical system according to claim 43, wherein the middle segment is monolithically formed in an electrically conductive material.

53. The high-power electrical system according to claim 43, wherein the middle segment is monolithically formed in a first end with the first end of the electrical conductor and monolithically formed in a second end with the second end of the electrical conductor.

54. The high-power electrical system according to claim 43, wherein the high-power electrical conductors is at least partly manufactured by an additive manufacturing process.

55. The high-power electrical system according to claim 43, wherein the middle segment comprising a plurality of conductor branches.

56. The high-power electrical system according to claim 43, wherein a cross-sectional area of the one or more conductor branches are equal to or below 200 mm.

57. A method of manufacturing, via an additive manufacturing process, a high-power electrical conductor including an internal channel, the method comprising steps of:
providing a first layer of electrically conductive material; and
providing a plurality of subsequent layers of the electrically conductive material thereby forming a first end, a middle segment and a second end of the high-power electrical conductor,
wherein the method is characterized in that a layer of the high-power electrical conductor added to a previous layer of the high-power electrical conductor is only partly covering the cross-sectional area the previous layer,
wherein the non-covered part of the previous layer at least partly forms an internal channel comprising a channel inlet and a channel outlet, and
wherein the internal channel, the channel inlet and channel outlet are provided in the middle section.

58. The method according to claim 57, wherein the part of the previous layer not covered by a subsequent layer is within the middle 95% of the previous layer, preferably within the middle 80% of the previous layer, most preferably within the middle 50% of the previous layer.

59. A high-power electrical conductor configured to distribute power in a high-power electrical system,
wherein the high-power electrical conductors is configured for being mechanically and electrically connected to a heat generating electrical component comprised by the high-power electrical system,
wherein the high-power electrical conductors comprising a first end space apart from a second end by a middle segment,
wherein the middle segment comprises at least one internal channel configured to guide a temperature regulating fluid,
wherein at least one of the first end and the second end is monolithically formed with the middle segment, and
wherein the at least one internal channel includes a channel inlet and a channel outlet, and
wherein the channel inlet and channel outlet are provided in the middle section.

60. The high-power electrical system according to claim 59, wherein the high-power electrical conductor comprises a plurality of channel inlets and/or a plurality of channel outlets.

61. The high-power electrical system according to claim 60, wherein at least part the plurality of channel inlet and/or the cooling channel outlet are provided in the middle segment.

62. The high-power electrical system according to claim 60, wherein at least part the plurality of channel inlet and/or the cooling channel outlet is provided in the first end or in the second end.
